(19) United States
(12) Patent Application Publication
(10) Pub. No.: US 2024/0206279 A1
(43) Pub. Date: Jun. 20, 2024

(54) SUPPORTING LAYER AND FLEXIBLE DISPLAY PANEL

(71) Applicant: Wuhan China Star Optoelectronics Semiconductor Display Technology Co., Ltd., Wuhan, Hubei (CN)

(72) Inventor: Wenqiang WANG, Wuhan, Hubei (CN)

(73) Assignee: Wuhan China Star Optoelectronics Semiconductor Display Technology Co., Ltd., Wuhan, Hubei (CN)

(21) Appl. No.: 17/263,934

(22) PCT Filed: Nov. 24, 2020
(86) PCT No.: PCT/CN2020/130977

§ 371 Date: Jun. 30, 2023

(30) Foreign Application Priority Data
Oct. 28, 2020 (CN) 202011170478.0

(51) Int. Cl. H10K 59/80

(52) U.S. Cl. CPC H10K 59/80

(57) ABSTRACT

A supporting layer and a flexible display panel are provided. Openings and notches are repeatedly disposed in the supporting layer, and a first striped hollow portion of the notch extends through an edge and/or a side of the supporting layer, such that an extensibility of a module stacked structure can be improved as a whole to ensure an adaptability and coordination between the supporting layer and film layers of the module stacked structure. Thus, a bending performance of an organic light emitted diode module is improved, a risk of the film layers being peeled off or broken is reduced, and a bending lifespan of the module stacked structure is improved.

### FIELD OF DISCLOSURE

The present disclosure relates to the field of display technologies, in particular to the field of flexible display technologies, and specifically to a supporting layer and a flexible display panel.

### BACKGROUND

In recent years, organic light emitted diode (OLED) display technologies have become increasingly mature. An OLED module stacked structure is based on light emitted diode (LED) technologies, and its thickness is significantly reduced, which makes it possible to commercialize flexible displays.

In recent years, various terminal manufacturers have successively introduced flexible folding and roll-up display electronic products, but a price is relatively high, which has resulted in relatively low product popularity. A low production yield of flexible displays is a direct cause. In the current stage of the production process of flexible display modules, a film material of the module stacked structure is peeled off, broken, etc., which will directly affect a lifespan of the product and the production yield. Generally, in a typical OLED module stacked structure, in order to ensure an overall flatness of the module, a bottom layer of material adjacent to the structure usually uses a thinner stainless steel plate (SUS, a stainless steel code) as a supporting layer.

However, an obvious difference between a modulus of the supporting layer and film layers and adhesive layers is usually 100 to 1000 times. The film layers are often peeled off from each other due to uneven force and deformation during a bending process. FIG. 1 is a physical diagram of an existing OLED module showing that an entire support structure and an adhesive layer are peeled off from each other and a supporting layer is broken. In view of this, in order to improve this failure, a bending area of the entire supporting layer is usually made into a grid shape, that is, a patterned structure. This solution effectively solves the peeling problem compared to the entire SUS. However, in a long-term bending fatigue test (the number of bending and folding is greater 200,000 times), local cracking often occur. This cracking problem directly affects the lifespan of the OLED module.

### SUMMARY OF DISCLOSURE

### Technical Problem

The present disclosure provides a supporting layer and a flexible display panel, which solves the problem of local cracking of the supporting layer in the long-term bending fatigue test.

### Technical Solution

In a first aspect, the present disclosure provides a supporting layer. The supporting layer includes a plurality of non-bending areas, a bending area disposed between two adjacent non-bending areas, and a plurality of openings and a plurality of notches repeatedly disposed in the bending area. The openings are arranged row by row along a first direction from one of the non-bending areas to the bending area, and a width direction of the openings is the same as the first direction. The notches are arranged with a row inserted between two adjacent rows along the first direction, and a width direction of the notches is the same as the first direction. Each of the notch includes a first striped hollow portion and a first arc-shaped hollow portion that are in contact with and connected to each other. A vertex of the first arc-shaped hollow portion is disposed on an extension centerline of the first striped hollow portion along a second direction, and the first striped hollow portion extends through an edge and/or a side of the supporting layer. The second direction is a length direction of the notches or the openings, and the first arc-shaped hollow portion includes a semi-elliptical shape.

Based on the first aspect, in a first embodiment of the first aspect, each of the openings include two second arc-shaped hollow portions and one second striped hollow portion. The two second arc-shaped hollow portions are in contact with and connected to both ends of the second striped hollow portion respectively, and a vertex of each the second arc-shaped hollow portions is disposed on an extension centerline of the second striped hollow portion along the second direction. Each of the second arc-shaped hollow portions includes the semi-elliptical shape.

Based on the first embodiment of the first aspect, in a second embodiment of the first aspect, a short radius of the semi-elliptical shape is parallel to the first direction, a long radius of the semi-elliptical shape is parallel to the second direction, and one end of the long radius coincides with the corresponding vertex.

Based on the second embodiment of the first aspect, in a third embodiment of the first aspect, a middle area of the second striped hollow portion includes a symmetrically widened hollow portion.

Based on the first embodiment of the first aspect, in a fourth embodiment of the first aspect, a length of the second striped hollow portion is greater than or equal to 3.7 mm.

Based on the first embodiment of the first aspect, in a fifth embodiment of the first aspect, a distance between two adjacent second arc-shaped hollow portions in the second direction or a distance between the first arc-shaped hollow portion and its adjacent second arc-shaped hollow portion in the second direction ranges from 100 μm to 240 μm.

Based on the first embodiment of the first aspect, in a sixth embodiment of the first aspect, a distance between two of the first striped hollow portions arranged in two adjacent rows and/or a distance between two of the second striped hollow portions arranged in two adjacent rows ranges from 60 μm to 140 μm.

Based on the first embodiment of the first aspect, in a seventh embodiment of the first aspect, a width of the second striped hollow portion ranges from 120 μm to 300 μm.

Based on the second embodiment of the first aspect, in an eighth embodiment of the first aspect, a length of the long radius is twice a length of the short radius.

Based on any of the foregoing embodiments of the first aspect, in a ninth embodiment of the first aspect, all the openings and the notches extend through the supporting layer.

Based on the ninth embodiment of the first aspect, in a tenth embodiment of the first aspect, the openings of adjacent rows are arranged repeatedly in a staggered arrangement.

Based on the fourth embodiment of the first aspect, in an eleventh embodiment of the first aspect, a length of the first striped hollow portion is less than or equal to the length of the second striped hollow portion, and the first arc-shaped hollow portion is the same as the second arc-shaped hollow portion.

In a second aspect, the present disclosure provides a flexible display panel, including a display functional layer and the supporting layer in any of the above embodiments. The supporting layer is disposed on one side of the display functional layer and is configured to support the display functional layer.

Based on the second aspect, in a first embodiment of the second aspect, the flexible display panel further includes a buffer layer. The buffer layer is disposed between the display functional layer and the supporting layer.

Based on the first embodiment of the second aspect, in a second embodiment of the second aspect, the flexible display panel further includes a protection film. The protection film is disposed on one side of the supporting layer away from the display functional layer, and is configured to protect the supporting layer.

### Advantageous Effect

The present disclosure provides the supporting layer and the flexible display panel. The openings and the notches are repeatedly disposed in the supporting layer, and the first striped hollow portion of the notch extends through the edge and/or the side of the supporting layer, such that an extensibility of the module stacked structure can be improved as a whole to ensure the deformation adaptability and coordination between the supporting layer and the film layers of the module stacked structure. Thus, a bending performance of the OLED module is improved, a risk of the film layers being peeled off or broken is reduced, a bending lifespan of the module stacked structure is improved, and a production yield of the product is improved.

### BRIEF DESCRIPTION OF DRAWINGS

FIG. 1 is a schematic diagram of an existing module stacked structure, showing a comparison of structures in which a full-surface supporting layer before bending and the full-surface supporting layer being peeled off and broken after bending.

FIG. 2 is a schematic diagram of a flexible display panel of an embodiment of the present disclosure.

FIG. 3 is a schematic diagram of a supporting layer in FIG. 2.

FIG. 4 is a schematic diagram of a bending area in FIG. 3.

FIG. 5 is a partial enlarged schematic diagram of FIG. 4.

FIG. 6 is a schematic diagram of an arc-shaped hollow portion in FIG. 5.

FIG. 7 is a physical comparison diagram of a stress distribution of the supporting layer.

FIG. 8 is a trend simulation diagram of a length L and a local peak stress.

FIG. 9 is a trend simulation diagram of a distance X and a local peak stress.

FIG. 10 is a trend simulation diagram of a distance Y and a local peak stress.

FIG. 11 is a trend simulation diagram of a width D and a local peak stress.

FIG. 12 is a physical schematic diagram of a corresponding arc-shaped hollow portion.

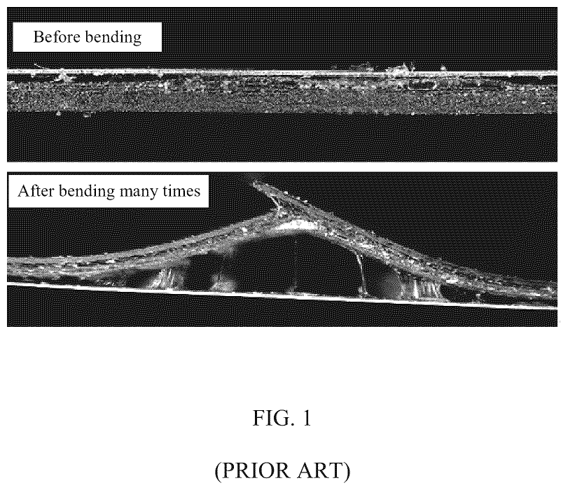

### DETAILED DESCRIPTION

In order to make purposes, technical solutions, and effects of the present disclosure clearer and specific, the present disclosure will be described in further detail with reference to the accompanying drawings and embodiments. It should be understood that the specific embodiments described herein are only used to explain the present disclosure, and are not used to limit the present disclosure.

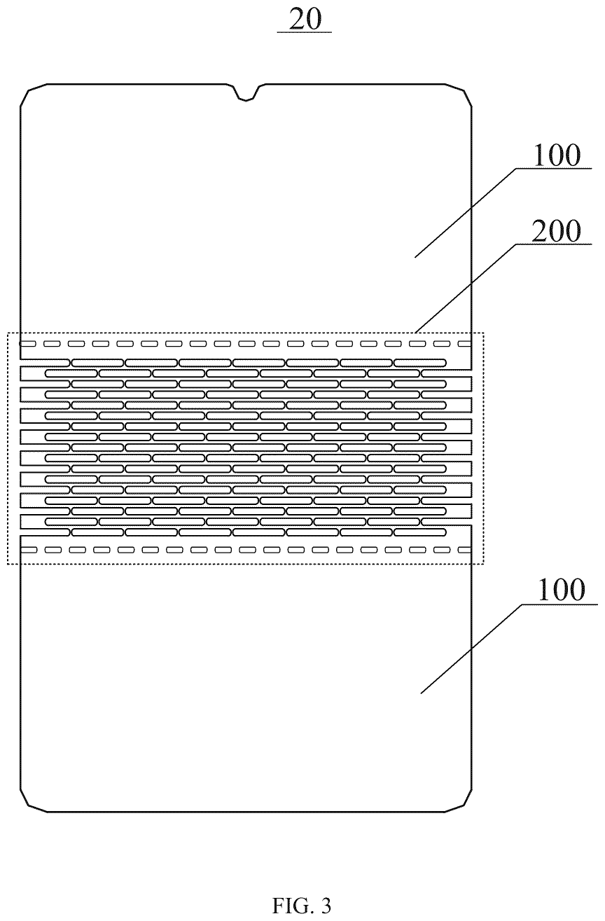

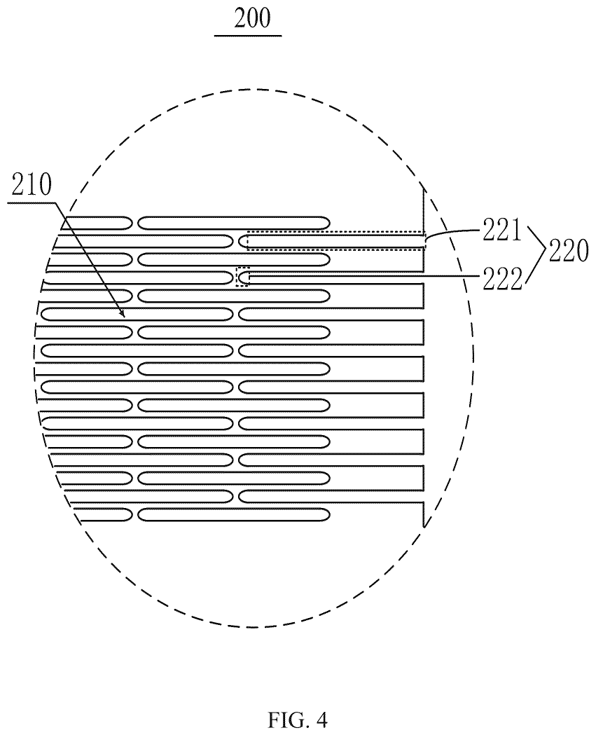

Referring to FIG. 3 to FIG. 4, an embodiment provides a supporting layer 20. Along a bending direction, the supporting layer 20 is divided into three areas. A middle area of the supporting layer 20 receives a relatively large and relatively concentrated force during a bending process, and is extremely prone to uneven force, uncoordinated deformation, and even breakage in severe cases. Thus, a structural design of the supporting layer 20 should fully consider the uniformity of the bending stress dispersion, avoid excessive local stress, which is beneficial to prolong a bending lifespan of the supporting layer 20. Accordingly, the middle area of the supporting layer 20 is set as a bending area 200, and the areas on both sides of the middle area on the supporting layer 20 are set as non-bending areas 100. In order to more evenly disperse the stress received by the supporting layer 20 during the bending process and make the supporting layer 20 have better extensibility in the bending area 200, openings 210 and notches 220 are repeatedly disposed in the bending area 200 of the supporting layer 20. The openings 210 are arranged row by row along a first direction (i.e. a bending direction) from one of the non-bending areas 100 to the bending area 200, and a width direction of the openings 210 is the same as the first direction. The notches 220 are arranged with a row inserted between two adjacent rows along the first direction. That is, the notches 220 can be arranged in odd or even rows, they can also be arranged in odd rows and even rows that are not adjacent to the odd rows, or they can also be arranged in even rows and odd rows that are not adjacent to the even rows. A width direction of the notches 220 is the same as the first direction. Each of the notch 220 includes a first striped hollow portion 221 and a first arc-shaped hollow portion 222 that are in contact with and connected to each other. A vertex of the first arc-shaped hollow portion 222 is disposed on an extension centerline of the first striped hollow portion 221 along a second direction, and the first striped hollow portion 221 extends through an edge and/or a side of the supporting layer 20. The second direction is a length direction of the notches 220 or the openings 210.

In should be understood that the openings 210 and the notches 220 are repeatedly disposed in the supporting layer 20, and the first striped hollow portion 221 of the notch 220 extends through the edge and/or the side of the supporting layer 20, such that an extensibility of the module stacked structure can be improved as a whole to ensure the deformation adaptability and coordination between the supporting layer 20 and the film layers of the module stacked structure. Thus, a bending performance of the OLED module is improved, a risk of the film layers being peeled off or broken is reduced, a bending lifespan of the module stacked structure is improved, and a production yield of the product is improved.

It should be noted that the openings 210 in this embodiment are disposed in a non-edge area of the bending area 200, and the notches 220 are disposed in an edge area of the bending area 200. In particular, the first striped hollow portion 221 of the notches 220 extends through the edge and/or the side of the supporting layer 20, which can greatly release the stress in the edge area and weaken a concentrated distribution of stress. The first arc-shaped hollow portion 222 is disposed relatively approximately the non-edge area. Because of its arc-shaped design, it can endure greater pulling force and has a good resisting force, which are beneficial to conduct and disperse the bending stress in the non-edge area.

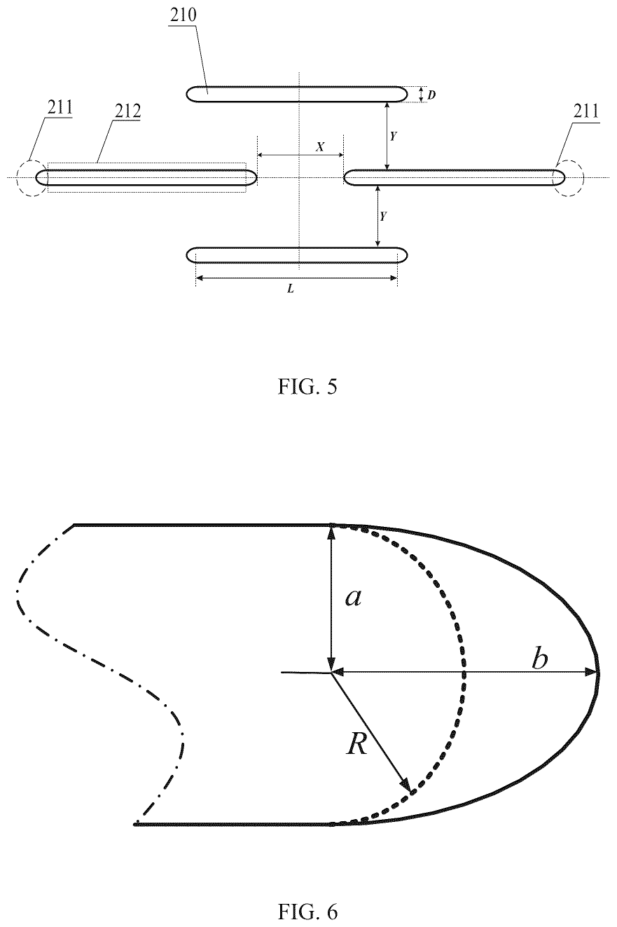

Referring to FIG. 5, in one of the embodiments, the openings 210 of adjacent rows may be, but not limited to, arranged repeatedly in a staggered arrangement. For example, in the arrangement of three adjacent rows, a first row is provided with a first opening, a second row is provided with two adjacent and non-connected second opening and third opening, and a third row is provided with a fourth opening. The first opening and the fourth opening are arranged symmetrically along their respective length directions. The second opening and the third opening are arranged symmetrically along their respective width directions. Also, a distance from the first opening to the second opening is equal to a distance from the first opening to the third opening. A distance from the fourth opening to the second opening is equal to a distance from the fourth opening to the third opening. An orthographic projection of the first opening overlaps with the second opening and the third opening. Also, an overlapping area of the orthographic projection of the first opening and the second opening and an overlapping area of the third opening may be, but not limited to, equal. In this embodiment, the openings 210 are arranged repeatedly in the staggered arrangement to further evenly distribute the bending stress.

In one of the embodiments, the openings 210 and the notches 220 are both hollow structures and extend through the supporting layer 20. It is understandable that in this embodiment, the openings 210 and the notches 220 are defined as a through structure design, which can uniformly disperse the stress generated during the bending process.

In one of the embodiments, the openings 210 include second arc-shaped hollow portions 211 and a second striped hollow portion 212. One end of the second striped hollow portion 212 is in contact with and connected to one of the second arc-shaped hollow portions 211. The other end of the second striped hollow portion 212 is in contact with and connected to another second arc-shaped hollow portion 211. A vertex of the second arc-shaped hollow portion 211 is disposed on an extension centerline of the second striped hollow portion 212 along a second direction, and the vertex is away from a center of the notch 220 or the opening 210.

Both the first arc-shaped hollow portion 222 and the second arc-shaped hollow portion 211 include a semi-elliptical shape, that is, a half of an ellipse. A short radius a of the semi-elliptical shape is parallel to the first direction, and an end point of the short radius a of the semi-elliptical shape is contact and connection points between the corresponding strip-shaped hollow portion and the corresponding arc-shaped hollow portion. A long radius b of the semi-elliptical shape is parallel to the second direction, and one end of the long radius b coincides with the corresponding vertex.

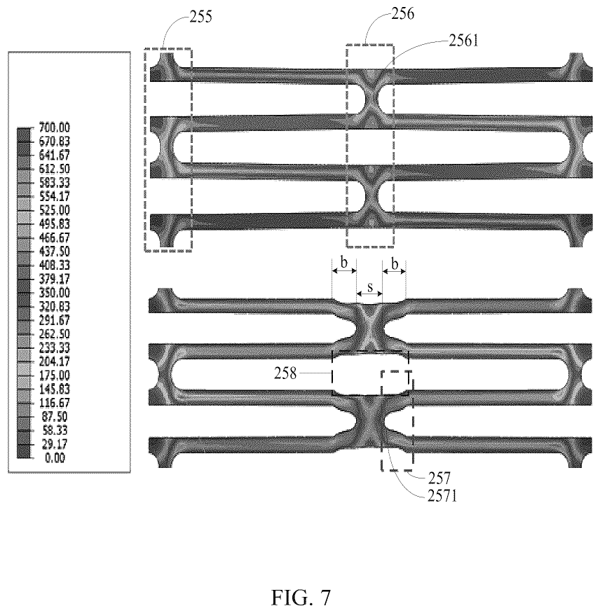

As shown in FIG. 7, in one of the embodiments, a middle area of the second striped hollow portion 212 is provided with a symmetrically widened hollow portion 258. A length of the hollow portion 258 is the sum of twice the length of the long radius b and a distance s between two adjacent second arc-shaped hollow portions 211 in the second direction. Alternatively, the length of the hollow portion is the sum of twice the length of the long radius b and a distance s between the first arc-shaped hollow portion 222 and its adjacent second arc-shaped hollow portion 211 in the second direction.

It should be noted that the design of the widened hollow portion 258 can reduce or weaken the stress at the connection portions of the second arc-shaped hollow portion 211 and the two adjacent second arc-shaped hollow portions 211.

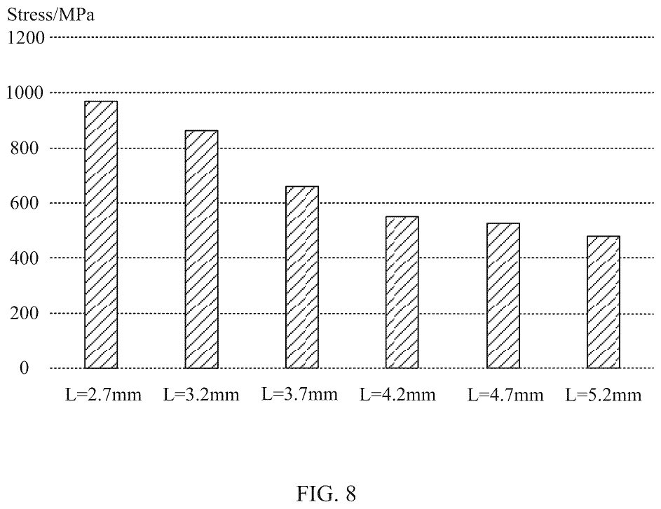

Referring to FIG. 5 to FIG. 11, as shown in FIG. 5 and FIG. 8, in one of the embodiments, as a length L of the second striped hollow portion 212 increases, a local peak stress received by the supporting layer 20 during the bending process gradually reduce. The length L of the second striped hollow portion 212 ranges from 2.7 mm to 5.2 mm. If the length L of the second striped hollow portion 212 is 2.7 mm, the corresponding local peak stress is approximately 1000 MPa. If the length L of the second striped hollow portion 212 is 3.2 mm, the corresponding local peak stress exceeds 800 MPa. If the length L of the second striped hollow portion 212 is 3.7 mm, the corresponding local peak stress exceeds 600 MPa. If the length L of the second striped hollow portion 212 is 4.2 mm, the corresponding local peak stress is approximately 600 MPa. If the length L of the second striped hollow portion 212 is 4.7 mm, the corresponding local peak stress is approximately 600 MPa, which is slightly less than the corresponding local peak stress if the length L of the second striped hollow portion 212 is 4.2 mm. If the length L of the second striped hollow portion 212 is 5.2 mm, the corresponding local peak stress is approximately 500 MPa. Therefore, considering the optimization of the local peak stress, the length L of the second striped hollow portion 212 can be selected to be greater than or equal to 3.7 mm.

It should be noted that the above simulation data is a corresponding trend graph, which is based on a distance X between two adjacent second arc-shaped hollow portions 211 in the second direction or the distance X between the first arc-shaped hollow portion 222 and its adjacent second arc-shaped hollow portions 211 in the second direction is 0.16 mm, a distance Y between the first striped hollow portion 221Y and/or the second striped hollow portion 212 of adjacent rows is 0.08 mm, and a width D of the first striped hollow portion 221 or the width D of the second striped hollow portion 212 is 0.15 mm

The length of the first striped hollow portion 221 is less than or equal to the length L of the second striped hollow portion 212.

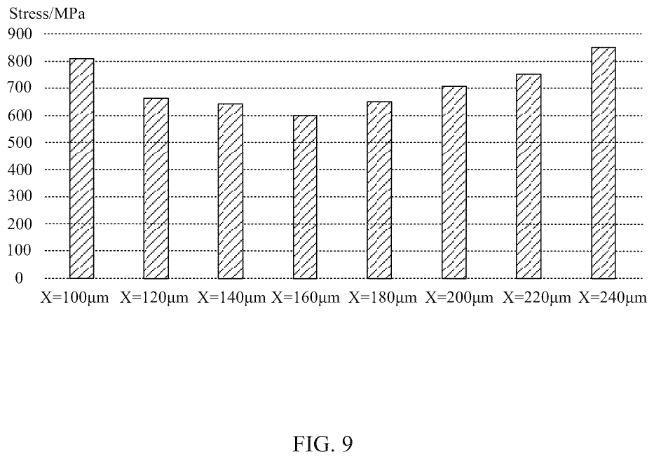

As shown in FIG. 5 and FIG. 9, in one of the embodiments, as the distance X between two adjacent second arc-shaped hollow portions 211 in the second direction or the distance X of the first arc-shaped hollow portion 222 and its adjacent second arc-shaped hollow portion 211 in the second direction ranging from 100 μm to 240 μm, the local peak stress first decreases and then increases. This shows that the distance X between two adjacent second arc-shaped hollow portions 211 in the second direction or the distance X between the first arc-shaped hollow portion 222 and its adjacent second arc-shaped hollow portions 211 in the second direction has a better selection range, which is not the larger the better, nor the smaller the better. During the change of the distance X between two adjacent second arc-shaped hollow portions 211 in the second direction or the distance X between the first arc-shaped hollow portion 222 and its adjacent second arc-shaped hollow portion 211 in the second direction from 100 μm, 120 μm, 140 μm, to 160 μm, the local peak stress decreases from approximately 800 MPa to approximately 600 MPa. During the change of the distance X between two adjacent second arc-shaped hollow portions 211 in the second direction or the distance X between the first arc-shaped hollow portion 222 and its adjacent second arc-shaped hollow portion 211 in the second direction from 160 μm, 180 μm, 200 μm, 220 μm, to 240 μm, the local peak stress increases from approximately 600 MPa to approximately 850 MPa. Therefore, as a better choice, the distance X between two adjacent second arc-shaped hollow portions 211 in the second direction or the distance X between the first arc-shaped hollow portion 222 and its adjacent second arc-shaped hollow portion 211 in the second direction can be selected in the range of 140 μm to 180 μm. Apparently, as a better solution to weaken the local peak stress, it can also be chosen to be around 160 μm.

It should be noted that the above simulation data is a corresponding trend graph, which is based on the length L of the second striped hollow portion 212 is 3.7 mm, a distance Y between the first striped hollow portion 221Y and/or the second striped hollow portion 212 of adjacent rows is 0.08 mm, and a width D of the first striped hollow portion 221 or a width D of the second striped hollow portion 212 is 0.15 mm.

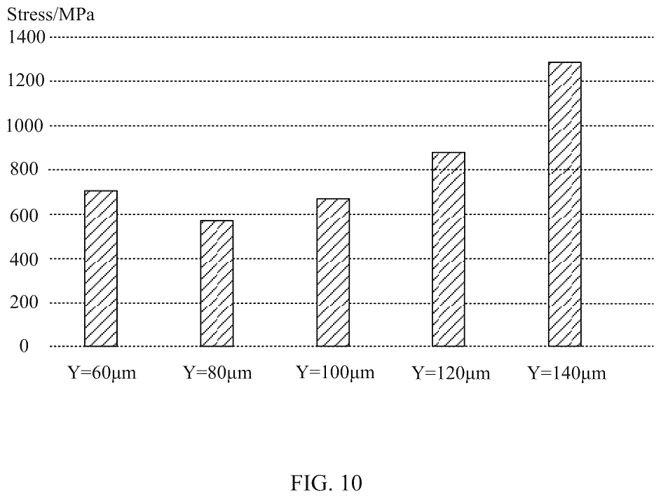

As shown in FIG. 5 and FIG. 10, in one of the embodiments, as the distance Y between the first striped hollow portion 221 and/or the second striped hollow portion 212 of adjacent rows increases from 60 μm to 140 μm, the local peak stress first decreases and then increases. This shows that the distance Y between the first striped hollow portion 221 and/or the second striped hollow portion 212 of adjacent rows has a better selection range, which is not the larger the better, nor the smaller the better. When the distance Y between the first striped hollow portion 221 and/or the second striped hollow portion 212 of adjacent rows increases from 60 μm to 80 μm, the local peak stress decreases from approximately 700 MPa to approximately 600 MPa. When the distance Y between the first striped hollow portion 221 and/or the second striped hollow portion 212 of adjacent rows increases from 80 μm, 100 μm, 120 μm, to 140 μm, the local peak stress increases from approximately 600 MPa to approximately 1300 MPa. Therefore, as a better choice, the distance Y between the first striped hollow portion 221 and/or the second striped hollow portion 212 of adjacent rows can be selected in the range of 60 μm to 100 μm. Apparently, as a better solution to weaken the local peak stress, it can also be chosen to be around 80 μm.

It should be noted that the above simulation data is a corresponding trend graph, which is based on the length L of the second striped hollow portion 212 is 3.7 mm, and the distance X between two adjacent second arc-shaped hollow portions 211 in the second direction or the distance X between the first arc-shaped hollow portion 222 and its adjacent second arc-shaped hollow portion 211 in the second direction is 0.16 mm, and the width D of the first striped hollow portion 221 or the width D of the second striped hollow portion 212 is 0.15 mm.

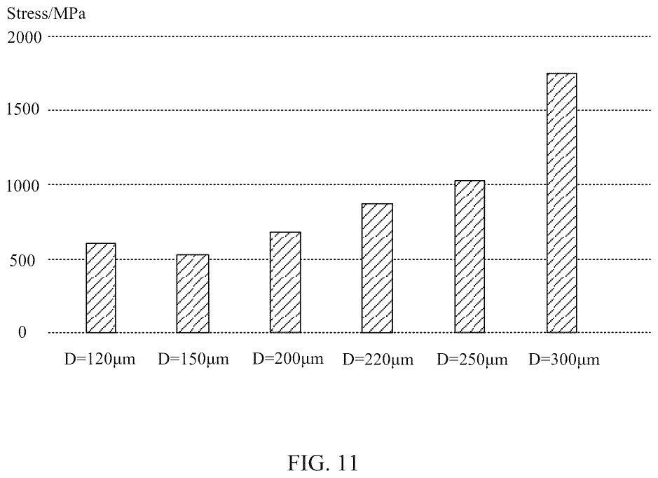

As shown in FIG. 5 and FIG. 11, in one of the embodiments, as the width D of the first striped hollow portion 221 or the width D of the second striped hollow portion 212 increases from 120 μm to 300 μm, the local peak stress first decreases and then increases. This shows that the width D of the first striped hollow portion 221 or the width D of the second striped hollow portion 212 has a better selection range, which is not the larger the better, nor the smaller the better. When the width D of the first striped hollow portion 221 or the width D of the second striped hollow portion 212 increases from 120 μm to 150 μm, the local peak stress decreases from approximately 600 MPa to approximately 500 MPa. When the width D of the first striped hollow portion 221 or the width D of the second striped hollow portion 212 increases from 150 μm, 200 μm, 220 μm, 250 μm, to 300 μm, the local peak stress increases from approximately 500 MPa to approximately 1700 MPa. Therefore, as a better choice, the distance Y between the first striped hollow portion 221 and/or the second striped hollow portion 212 of adjacent rows can be selected in the range of 120 μm to 200 μm. Apparently, as a better solution to weaken the local peak stress, it can also be chosen to be around 150 μm.

It should be noted that the above simulation data is a corresponding trend graph, which is based on the length L of the second striped hollow portion 212 is 3.7 mm, and the distance X between two adjacent second arc-shaped hollow portions 211 in the second direction or the distance X between the first arc-shaped hollow portion 222 and its adjacent second arc-shaped hollow portion 211 in the second direction is 0.16 mm, and the width D of the first striped hollow portion 221 or the width D of the second striped hollow portion 212 is 0.08 mm.

As shown in FIG. 4 and FIG. 6, in one of the embodiments, when the first arc-shaped hollow portion 222 and/or the second arc-shaped hollow portion 211 are formed as a semi-ellipse, the length of the long radius b is twice the length of the short radius a. For example, the length of the short radius a may be but not limited to 0.2 mm, and correspondingly, the length of the long radius b may be but not limited to 0.4 mm. In comparison with the first arc-shaped hollow portion 222 and/or the second arc-shaped hollow portion 211 being a circle with a radius R, the above shape has a better stress dispersion performance.

The first arc-shaped hollow portion 222 and the second arc-shaped hollow portion 211 may be the same, but not limited to.

As shown in FIG. 7, a numerical part on a left represents a local stress distribution in a corresponding area. For example, an area 255 and an area 256 adopt the supporting layer 20 of the traditional technical solution, and the local stress distribution is concentrated. A stress value near a stress point 2561 reaches 636.5 MPa, and after optimization of the relevant embodiments in the present disclosure, the stress distribution is improved. For example, after improvement in an area 257 where the original stress is concentrated, the stress value near a stress point 2571 is reduced to 534.9 MPa, and a peak stress is reduced by approximately 16%, which improves the situation where the stress distribution is relatively concentrated.

In summary, through the above a plurality of sets of stress trend graphs with different eigenvalues, and based on a fatigue limit value of material of the supporting layer 20 of 800 MPa as an optimization target reference value, it can be determined that L≥3.7 mm, X is 0.16 mm, Y is 0.08 mm, D=0.15 mm, a is 0.2 mm, and b is 0.4 mm, a better supporting layer 20 can be obtained.

It is understandable that the relevant data provided in the embodiments of the present disclosure has been applied to actual production, and after a finite element simulation analysis technology and a simulation verification of a shape optimization algorithm, it can be confirmed that it can effectively reduce the local cracking of the supporting layer 20 during the bending process. Therefore, the bending lifespan of the supporting layer 20 in the module stacked structure is improved as a whole, the production yield of the product is improved, and the comprehensive use cost is reduced.

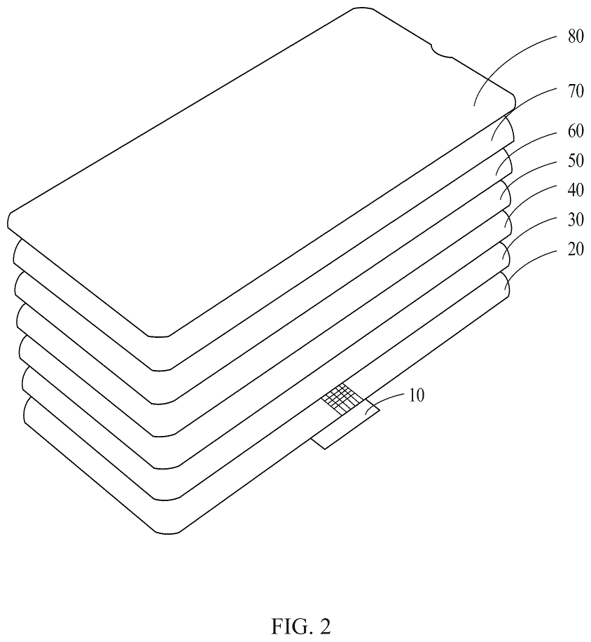

As shown in FIG. 2, in one of the embodiments, the present disclosure provides a flexible display panel, which includes a display functional layer and the supporting layer 20 in any of the above embodiments. The supporting layer 20 is disposed on one side of the display functional layer and configured to support the display functional layer.

It should be noted that the display functional layer includes a substrate 40, a display layer 50, a polarizer 60, an optical adhesive 70, and a protective cover plate 80, which are disposed layer-by-layer, in a direction from being close to the supporting layer 20 to away from the supporting layer 20.

In one of the embodiments, the flexible display panel further includes a buffer layer 30, and the buffer layer 30 is disposed between the display functional layer and the supporting layer 20.

In one of the embodiments, the flexible display panel further includes a protection film 10, which is disposed on one side of the supporting layer 20 away from the display functional layer, and is configured to protect the supporting layer 20.

The protective cover 80 is made of a transparent polymer material, which has good optical properties, scratch resistance, and abrasion resistance, and plays a role in protecting the module stacked structure. The optical adhesive 70 is a colorless and transparent adhesive with good light transmittance, high bonding strength, and small curing shrinkage. The polarizer 60 is a polymer film layer with high transmittance, high degree of polarization optical characteristics, high temperature and humidity resistance, and the like. The supporting layer 20 is mainly made of manganese-containing special thin steel sheets, which are prepared through special processes such as annealing and tempering, and have good toughness and strength.

In should be understood that, in the flexible display panel of the embodiment of the present disclosure, the openings 210 and the notches 220 are repeatedly disposed in the supporting layer 20, and the first striped hollow portion 221 of the notch 220 extends through the edge and/or the side of the supporting layer 20, such that an extensibility of the module stacked structure can be improved as a whole to ensure the deformation adaptability and coordination between the supporting layer 20 and the film layers of the module stacked structure. Thus, a bending performance of the OLED module is improved, a risk of the film layers being peeled off or broken is reduced, a bending lifespan of the module stacked structure is improved, and a production yield of the product is improved.

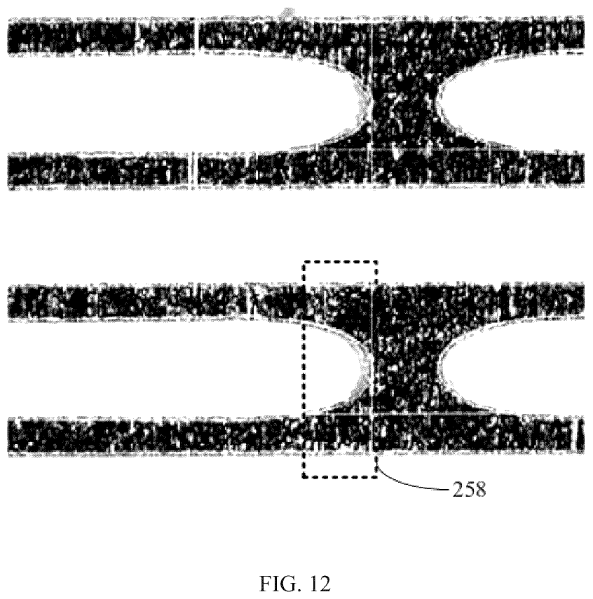

As shown in FIG. 12, it should be noted that when the first arc-shaped hollow portion 222 and/or the second arc-shaped hollow portion 211 in the present disclosure are semi-elliptical, there are processing errors in and near the portion 258. In actuality, the length of the long radius b of the first arc-shaped hollow portion 222 and/or second arc-shaped hollow portions 211 on a side close to the substrate 40 is greater than the length of the long radius b of the first arc-shaped hollow portion 222 and/or second arc-shaped hollow portions 211 on a side close to the protection film 10. Moreover, an arc vertex of the first arc-shaped hollow portion 222 and/or the second arc-shaped hollow portion 211 includes a slight slope.

It should be noted that the supporting layer 20 and flexible display panel provided by the present disclosure can be, but not limited to, applied to flat phones, OLED modules, full-screen phones, and can also be applied to tablets.

It can be understood that for those of ordinary skill in the art, equivalent replacements or changes can be made according to the technical solutions of the present disclosure and its inventive concept, and all these changes or replacements shall fall within the protection scope of the appended claims of the present disclosure.

1. A supporting layer, comprising a plurality of non-bending areas, a bending area disposed between two adjacent non-bending areas, and a plurality of openings and a plurality of notches repeatedly disposed in the bending area,
wherein the openings are arranged row by row along a first direction from one of the non-bending areas to the bending area, and a width direction of the openings is the same as the first direction;
wherein the notches are arranged with a row inserted between two adjacent rows along the first direction, and a width direction of the notches is the same as the first direction;
wherein each of the notch comprises a first striped hollow portion and a first arc-shaped hollow portion that are in contact with and connected to each other, a vertex of the first arc-shaped hollow portion is disposed on an extension centerline of the first striped hollow portion along a second direction, and the first striped hollow portion extends through an edge and/or a side of the supporting layer; and
wherein the second direction is a length direction of the notches or the openings, and the first arc-shaped hollow portion comprises a semi-elliptical shape.

2. The supporting layer as claimed in claim 1, wherein each of the openings comprises two second arc-shaped hollow portions and one second striped hollow portion, the two second arc-shaped hollow portions are in contact with and connected to both ends of the second striped hollow portion respectively, and a vertex of each the second arc-shaped hollow portions is disposed on an extension centerline of the second striped hollow portion along the second direction; and
wherein each of the second arc-shaped hollow portions comprises the semi-elliptical shape.

3. The supporting layer as claimed in claim 2, wherein a short radius of the semi-elliptical shape is parallel to the first direction, a long radius of the semi-elliptical shape is parallel to the second direction, and one end of the long radius coincides with the corresponding vertex.

4. The supporting layer as claimed in claim 3, wherein a middle area of the second striped hollow portion comprises a symmetrically widened hollow portion.

5. The supporting layer as claimed in claim 2, wherein a length of the second striped hollow portion is greater than or equal to 3.7 mm.

6. The supporting layer as claimed in claim 2, wherein a distance between two adjacent second arc-shaped hollow portions in the second direction or a distance between the first arc-shaped hollow portion and its adjacent second arc-shaped hollow portion in the second direction ranges from 100 μm to 240 μm.

7. The supporting layer as claimed in claim 2, wherein a distance between two of the first striped hollow portions arranged in two adjacent rows and/or a distance between two of the second striped hollow portions arranged in two adjacent rows ranges from 60 μm to 140 μm.

8. The supporting layer as claimed in claim 2, wherein a width of the second striped hollow portion ranges from 120 μm to 300 μm.

9. The supporting layer as claimed in claim 3, wherein a length of the long radius is twice a length of the short radius.

10. The supporting layer as claimed in claim 1, wherein all the openings and the notches extend through the supporting layer.

11. The supporting layer as claimed in claim 10, wherein the openings of adjacent rows are arranged repeatedly in a staggered arrangement.

12. The supporting layer as claimed in claim 5, wherein a length of the first striped hollow portion is less than or equal to the length of the second striped hollow portion, and the first arc-shaped hollow portion is the same as the second arc-shaped hollow portion.

13. A flexible display panel, comprising:
a display functional layer; and
the supporting layer according to claim 1, wherein the supporting layer is disposed on one side of the display functional layer and is configured to support the display functional layer.

14. The flexible display panel as claimed in claim 13, further comprising a buffer layer, wherein the buffer layer is disposed between the display functional layer and the supporting layer.

15. The flexible display panel as claimed in claim 14, further comprising a protection film, wherein the protection film is disposed on one side of the supporting layer away from the display functional layer, and is configured to protect the supporting layer.

16. The flexible display panel as claimed in claim 13, wherein each of the openings comprises two second arc-shaped hollow portions and one second striped hollow portion, the two second arc-shaped hollow portions are in contact with and connected to both ends of the second striped hollow portion respectively, and a vertex of each the second arc-shaped hollow portions is disposed on an extension centerline of the second striped hollow portion along the second direction; and
wherein each of the second arc-shaped hollow portions comprises the semi-elliptical shape.

17. The flexible display panel as claimed in claim 16, wherein a short radius of the semi-elliptical shape is parallel to the first direction, a long radius of the semi-elliptical shape is parallel to the second direction, and one end of the long radius coincides with the corresponding vertex.

18. The flexible display panel as claimed in claim 17, wherein a middle area of the second striped hollow portion comprises a symmetrically widened hollow portion.

19. The flexible display panel as claimed in claim 16, wherein a length of the second striped hollow portion is greater than or equal to 3.7 mm.

20. The flexible display panel as claimed in claim 16, wherein a distance between two adjacent second arc-shaped hollow portions in the second direction or a distance between the first arc-shaped hollow portion and its adjacent second arc-shaped hollow portion in the second direction ranges from 100 μm to 240 μm.
